(19) United States
(12) Patent Application Publication
(10) Pub. No.: US 2021/0288174 A1
(43) Pub. Date: Sep. 16, 2021

(54) SEMICONDUCTOR DEVICE

(71) Applicant: LAPIS Semiconductor Co., Ltd., Yokohama (JP)

(72) Inventor: Taku SHIBAGUCHI, Yokohama (JP)

(73) Assignee: LAPIS Semiconductor Co., Ltd., Yokohama (JP)

(21) Appl. No.: 17/197,672

(22) Filed: Mar. 10, 2021

(30) Foreign Application Priority Data
Mar. 16, 2020 (JP) 2020-044928

(51) Int. Cl. H01L 29/788; H01L 27/11519; H01L 27/11524; H01L 29/66; G11C 16/04; G11C 16/14

(52) U.S. Cl. CPC H01L 29/788; H01L 27/11519; G11C 16/14; H01L 29/66825; G11C 16/0483; H01L 27/11524

(57) ABSTRACT

A semiconductor device includes a first well of a first conductivity type formed to extend inwardly from a first region on one surface of the semiconductor substrate; a second well of a second conductivity type formed to extend inwardly from a second region separated from the first region on said surface of the semiconductor substrate; a third well of the first conductivity type formed to extend inwardly from a third region separated from the second region on said surface of the semiconductor substrate; and a conductive layer formed over the first region, the second region, and the third region on said surface of the semiconductor substrate. A recess is formed to expose a side face of the first well, and the conductive layer is formed to cover a top surface of the first well exposed in the first region and at least part of the side face.

### CROSS REFERENCE TO RELATED APPLICATION

This application is based upon and claims the benefit of priority of the prior Japanese Patent Application No. 2020-044928, filed on Mar. 16, 2020, the entire contents of which are incorporated herein by reference.

### TECHNICAL FIELD

The present invention relates to a semiconductor device.

### BACKGROUND ART

One of known examples of a non-volatile memory storage device is a non-volatile memory that stores and erases data by changing the state of charge accumulation in a floating gate, which is an electrically isolated floating electrode layer. For the structure of such a non-volatile memory, a so-called stacked structure in which a polysilicon layer functioning as a floating gate and a polysilicon layer functioning as a control gate are layered is commonly used.

As opposed to the stacked non-volatile memory, a non-volatile memory of a single-layer polysilicon type is known, which is constituted of a single layer polysilicon (Japanese Patent Application Laid-open Publication No. H9-129760, for example). In a non-volatile memory of the single-layer polysilicon type, the first well region functioning as the control gate, the second well region functioning as the read-out gate, and the third well region functioning as the tunnel gate are formed near the surface layer of the semiconductor substrate, for example. A floating gate made of a tunnel oxide film and a single-layer polysilicon is formed on the substrate so as to cover the first well region to the third well region.

In an area of the first well region, an area of the second well region, and an area of the third well region that each face the floating gate across the tunnel oxide film, capacitors respectively corresponding to the floating gate, the read-out gate, and the tunnel gate are formed. Then, by applying a voltage to each of the control gate, the read-out gate, and the tunnel gate to change the potential of the floating gate, operations such as data writing and data erasure are performed.

To write data, for example, a voltage Vw (Vw>0V) is applied to the control gate, 0 v is applied to the tunnel gate, and an intermediate voltage Vc (0V<Vc<Vw) is applied to the read-out gate, respectively. The potential of the floating gate rises in accordance with the voltage Vw applied to the control gate, and electrical charges flow from the third well region (or tunnel gate) to the floating gate. On the other hand, to erase data, 0V is applied to the control gate, Vw is applied to the tunnel gate, and the intermediate voltage Vc is applied to the read-out gate, respectively. The potential of the floating gate drops in accordance with the voltage 0V applied to the control gate, and electrical charges accumulated in the floating gate move to the third well region.

### SUMMARY OF THE INVENTION

### Problems to be Solved by the Invention

In the non-volatile memory of the single-layer polysilicon type described above, “write characteristics” that indicate the writing speed to the memory cell and the voltage required for writing are important. In data writing, the higher the potential of the floating gate, the easier it is to inject electric charges from the tunnel gate to the floating gate. Thus, in terms of the write characteristics, it is preferable that the electrostatic capacity of the control gate (referred to as the write capacity hereinafter) be larger than the electrostatic capacity of the tunnel gate (referred to as the erasure capacity hereinafter).

Generally, the capacity of a capacitor such as a flat plate capacitor is in proportion to the electrode area. In the single-layer polysilicon type non-volatile memory described above, the size of the area where the floating gate and the control gate overlap corresponds to the “electrode area” in the write capacity. Therefore, in order to increase the write capacity, it is necessary to increase the size of the area where the control gate and the floating gate overlap. As a result, the unit area of the memory cell increases and therefore, the chip size also increases.

The present invention was made in view of the problem described above, and an object thereof is to provide a non-volatile memory with a small area and sufficient capacity.

A semiconductor device of the present invention is a semiconductor device that constitutes a non-volatile memory, including: a semiconductor substrate; a first well of a first conductivity type formed to extend inwardly from a first region on a surface of the semiconductor substrate; a second well of a second conductivity type having an opposite polarity to the first conductivity type, the second well being formed to extend inwardly from a second region separated from the first region on the surface of the semiconductor substrate; a third well of the first conductivity type formed to extend inwardly from a third region separated from the second region on the surface of the semiconductor substrate; and a conductive layer formed over the first region, the second region, and the third region on the surface of the semiconductor substrate, wherein a recess is formed in the surface to expose a side face of the first well in at least part of a periphery of the first region, and wherein the conductive layer is formed to cover a top surface of the first well exposed in the first region and at least part of the side face of the first well exposed in the recess.

A semiconductor device of the present invention includes: a semiconductor substrate having a first well of a first conductivity type formed to extend inwardly from a first region on a surface of the semiconductor substrate, a second well of a second conductivity type having an opposite polarity to the first conductivity type, the second well being formed to extend inwardly from a second region separated from the first region on the surface of the semiconductor substrate, and a third well of the first conductivity type formed to extend inwardly from a third region separated from the second region on the surface of the semiconductor substrate; a separation layer that extends inwardly from a fourth region between the first region and the second region on the surface of the semiconductor substrate; and a conductive layer formed over the first region, the second region, the third region, and the fourth region on the surface of the semiconductor substrate, the conductive layer having a part thereof sandwiched between the first well and the separation layer in a direction along which the first region and the second region are separated.

A manufacturing method for a semiconductor device of the present invention is a manufacturing method for a semiconductor device that constitutes a non-volatile memory, including: a step of forming a first well of a first conductivity type to extend inwardly from a first region on a surface of a semiconductor substrate, and a third well of the first conductivity type to extend inwardly from a third region separated from the first region on the surface of the semiconductor substrate; a step of forming a second well of a second conductivity type having an opposite polarity to the first conductivity type, the second well being formed to extend inwardly from a second region located between the first region and the third region on the surface of the semiconductor substrate; a step of forming a separation layer that extends inwardly from a region located in a border between the first region and the second region on the surface of the semiconductor substrate; a step of forming a recess in the separation layer to expose part of a side face of the first well in a border between the separation layer and the first well; and a step of forming a conductive layer to cover a top surface of the first well exposed in the first region and at least part of the side face of the first well exposed in the recess.

According to the semiconductor device of the present invention, it is possible to reduce the area of a non-volatile memory while maintaining the memory cell capacity.

### BRIEF DESCRIPTION OF THE DRAWINGS

FIG. 1 is a top view illustrating a configuration of a semiconductor device of Embodiment 1 of the present invention.

FIG. 2 is a cross-sectional view of the semiconductor device of FIG. 1 taken along the X-X line.

FIG. 3 is a circuit diagram illustrating a single-layer polysilicon type memory cell as an equivalent circuit.

FIG. 4 is a flowchart showing manufacturing steps of the semiconductor device.

FIG. 5A is a cross-sectional view along the X-X line in a first and third well regions formation process.

FIG. 5B is a cross-sectional view along the X-X line in a second well region formation process.

FIG. 5C is a cross-sectional view along the X-X line in a surface etching process.

FIG. 5D is a cross-sectional view along the X-X line in an element separation layer formation process.

FIG. 6A is a cross-sectional view along the X-X line in a step formation process.

FIG. 6B is a cross-sectional view along the X-X line in a tunnel oxide film formation process.

FIG. 6C is a cross-sectional view along the X-X line in a gate polysilicon formation process.

FIG. 7 is a top view illustrating a configuration of a semiconductor device of Embodiment 2 of the present invention.

FIG. 8 is a top view illustrating a configuration of a semiconductor device of a modification example of Embodiment 2.

FIG. 9 is a cross-sectional view of the semiconductor device of FIG. 8 taken along the Y-Y line.

### DETAILED DESCRIPTION OF EMBODIMENTS

Preferred embodiments of the present invention will be described in detail below. In the descriptions of respective embodiments below and appended diagrams, the same reference characters are given to parts that are substantially the same as each other or equivalent to each other.

### Embodiment 1

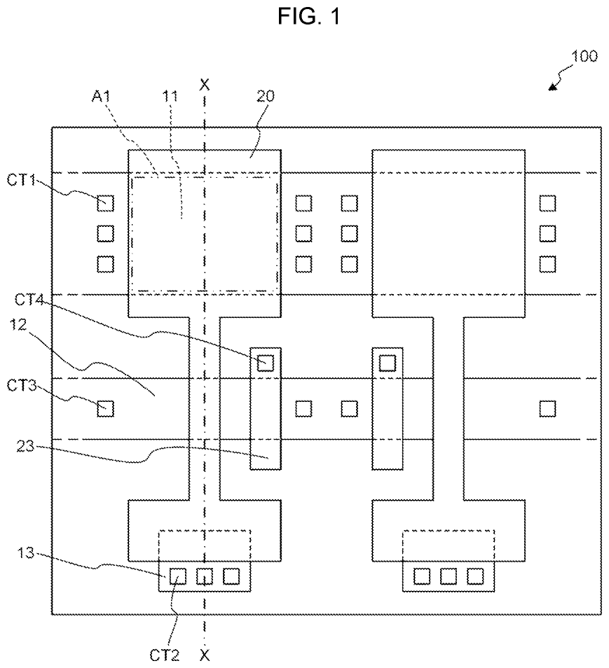

FIG. 1 is a top view of a semiconductor device 100 of this embodiment, viewed from above the surface where the elements are formed. The semiconductor device 100 is a semiconductor device that constitutes a memory cell of a non-volatile semiconductor memory of the single-layer polysilicon type.

The semiconductor device 100 has a semiconductor substrate 10, and a first well region 11, a second well region 12, and a third well region 13 formed to extend inwardly from the first surface (element formation surface) of the semiconductor substrate 10. On the first surface of the semiconductor substrate 10, a gate polysilicon 20 is formed over the first well region 11, the second well region 12, and the third well region 13.

The semiconductor substrate 10 is constituted of a Si (silicon) substrate, for example, and has a rectangular shape in a top view.

The first well region 11 and the third well region 13 are well regions of the first conductivity type (N-type in this embodiment). On the other hand, the second well region 12 is a well region of the second conductivity type (P-type in this embodiment) that has an opposite polarity from the first conductivity type.

The first well region 11 functions as the active area of the semiconductor memory. The surface of the first well region 11 exposed on the first surface of the semiconductor substrate 10 (referred to simply as the surface of the first well region 11 below) has a band-like shape in a top view. A portion of the first well region 11 covered by the gate polysilicon 20 functions as the control gate of the semiconductor memory. In this embodiment, a region in the first surface of the semiconductor substrate 10 where the top surface of the first well region 11 covered by the gate polysilicon 20 is located is referred to as the first region A1 (indicated by the dot-dot dashed line in FIG. 1).

Near the surface of the first well region 11 located outside the first region A1, an N-type diffusion layer (not illustrated in the figure) is formed, and a plurality of contacts CT1 made of a conductive material such as tungsten are connected to the diffusion layer. The diffusion layer and the contacts CT1 are formed in a region on the surface of the first well region 11 not covered by the gate polysilicon 20, and are exposed on the first surface of the semiconductor substrate 10.

The second well region 12 constitutes a read-out field effect transistor. The surface of the second well region 12 exposed on the first surface of the semiconductor substrate 10 (referred to simply as the surface of the second well region 12 below) has a band-like shape that extends in parallel with the first well region 11 in a top view. The second well region 12 is formed to extend toward the inner part of the semiconductor substrate 10 from a location (second region) separated from the first region A1 on the first surface of the semiconductor substrate 10.

The third well region 13 constitutes erasure areas of the semiconductor memory. The third well region 13 is formed to extend toward the inner part of the semiconductor substrate 10 from a location (third region) separated from the second region on the first surface of the semiconductor substrate 10. The third region faces the first region A1 across the second region. That is, the third well region 13 is formed in a position that faces the first well region 11 across the second well region 12. The surface of the third well region 13 exposed on the first surface of the semiconductor substrate 10 (referred to simply as the surface of the third well region 13 below) has a rectangular shape in a top view.

In the third well region 13, an N-type diffusion layer (not illustrated in the figure) is formed, and a plurality of contacts CT2 made of a conductive material such as tungsten are connected to the diffusion layer. The diffusion layer and the contacts CT2 are formed in a region on the surface of the third well region 13 not covered by the gate polysilicon 20, and are exposed on the first surface of the semiconductor substrate 10. A portion of the third well region 13 covered by the gate polysilicon 20 functions as the tunnel gate of the semiconductor memory.

The gate polysilicon 20 is a single conductive layer made of a polysilicon film. The gate polysilicon 20 is formed to cover the first well region 11, the second well region 12, and the third well region 13, such that the surface of each region is partially exposed. In this embodiment, the gate polysilicon 20 is constituted of a rectangular portion that covers the surface of the first well region 11 (referred to simply as the first rectangular portion below), a rectangular portion that partially covers the surface of the third well region 13 (referred to simply as the second rectangular portion below), and a band-shaped portion that traverses the surface of the second well region 12 and connects from the first rectangular portion to the second rectangular portion (referred to simply as the band-shaped portion below) in a top view. The band-shaped portion of the gate polysilicon 20 and the second well region 12 extend such that the respective longitudinal directions intersect with each other.

A selector transistor 23 is formed to cover a part of the surface of the second well region 12. The selector transistor 23 has a rectangular shape in a top view, for example, and is arranged such that the longitudinal direction intersects with the longitudinal direction of the section of the second well region 12 exposed on the first surface of the semiconductor substrate 10.

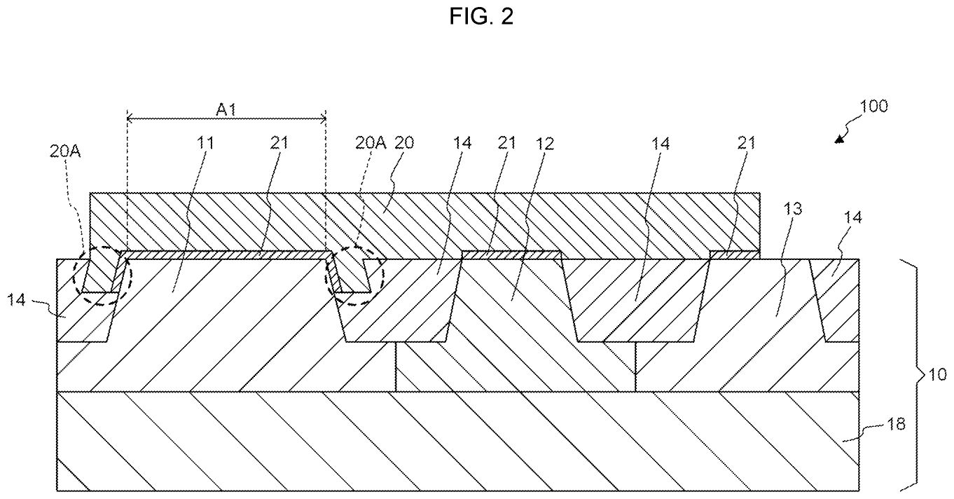

FIG. 2 is a cross-sectional view taken along the X-X line of FIG. 1.

The first well region 11, the second well region 12, and the third well region 13 are formed to extend inwardly from the first surface of the semiconductor substrate 10. In FIG. 2, the portion where the first well region 11, the second well region 12 or the third well region 13 is not formed is illustrated as a silicon substrate 18.

An element isolation region 14 made of an oxide film is formed near the surface layer portion of each of the first well region 11, the second well region 12, and the third well region 13. That is, the element isolation region 14 is formed to extend inwardly from the first surface of the semiconductor substrate 10. The element isolation region 14 has the STI (shallow trench isolation) structure. The element isolation region 14 is not illustrated in FIG. 1.

The element isolation region 14 between the first well region 11 and the second well region 12 (or, the element isolation region 14 formed to extend inwardly from a region between the first region A1 and the second region on the first surface of the semiconductor substrate 10) has a step in a portion adjacent to the first well region 11. In other words, the step is a recess formed in the first surface of the semiconductor substrate 10 in the periphery of the first region A1, exposing part of the side faces of the first well region 11.

A tunnel oxide film 21 is formed between the gate polysilicon 20 and the surfaces of the first well region 11, the second well region 12, and the third well region 13. The tunnel oxide film 21 is constituted of a silicon oxide film, for example. The tunnel oxide film 21 is formed to cover the respective surface areas of the first well region 11, the second well region 12, and the third well region 13 that are exposed on the semiconductor substrate 10.

The gate polysilicon 20 has a flat plate portion formed to cover the surfaces of the first well region 11, the second well region 12, and the third well region 13, and a ridge 20A protruding from the flat plate portion toward the inner part of the semiconductor substrate 10 (as encircled by the broken line circles in FIG. 2). The flat plate portion of the gate polysilicon 20 includes the first rectangular portion, the second rectangular portion, and the band-shaped portion in a top view as described above. The first rectangular portion covers the surface of the first well region 11 exposed in the first region A1 on the first surface of the semiconductor substrate 10.

The ridge 20A of the gate polysilicon 20 is located directly below the first rectangular portion in a top view. The ridge 20A is disposed in the step (recess) of the element isolation region 14, which is formed at the border between the first well region 11 and the element isolation region 14, and covers part of the side surface of the first well region 11 exposed by this step. That is, the gate polysilicon 20 is formed to cover the top surface of the first well region 11 (that is, the surface exposed on the first surface of the semiconductor substrate 10) and part of the side face of the first well region 11 facing the element isolation region 14.

In this embodiment, the side faces extending toward the inner part of the semiconductor substrate 10 from the two sides of the rectangular portion of the first well region 11 exposed in the first region A1 (that is, the side faces facing the element isolation region 14) partially face the ridge 20A of the gate polysilicon 20 with the tunnel oxide film 21 interposed therebetween.

The gate polysilicon 20 is a conductive layer functioning as the floating gate of the memory cell of the semiconductor memory constituted of the semiconductor device 100. Also, as described above, the portions of the first well region 11 and the third well region 13 covered by the gate polysilicon 20 are well regions that function as the control gate and the tunnel gate, respectively, that are used when data is written into the memory cell or erased from the memory cell. The second well region 12 is a well region functioning as the read-out gate that is used when data is read out from the memory cell.

When data is to be written, for example, a voltage Vw (Vw>0V) is applied to the contacts CT1, and 0V is applied to the contacts CT2. As a result, the gate polysilicon 20 has a potential that is close to the voltage Vw, which draws electrical charges from the third well region 13 to the gate polysilicon 20. On the other hand, when data is to be erased, 0V is applied to the contacts CT1, and the voltage Vw is applied to the contacts CT2. As a result, the gate polysilicon 20 has a potential that is close to 0V, which draws electrical charges from the gate polysilicon 20 to the third well region 13. The tunnel oxide film 21 functions as a tunnel oxide film when electrical charges move from the gate polysilicon 20 to the third well region 13.

The contacts CT3 connected to the second well region 12 have applied thereto an intermediate voltage Vc (0<Vc<Vw) when data is to be written or erased. When data is to be read out, a read-out voltage corresponding to the state of the charge accumulation in the gate polysilicon 20 is made to flow through the second well region 12.

In the semiconductor device 100 of this embodiment, the gate polysilicon 20 is formed to cover part of the side faces of the first well region 11 next to the element isolation region 14, in addition to the top surface of the first well region 11. This makes it possible to achieve a higher data writing performance than that of other memory cells in which the gate polysilicon 20 covers only the top surface of the first well region 11 (or in other words, the gate polysilicon 20 does not cover part of the side faces of the first well region 11, unlike the semiconductor device 100 of this embodiment). This will be explained below.

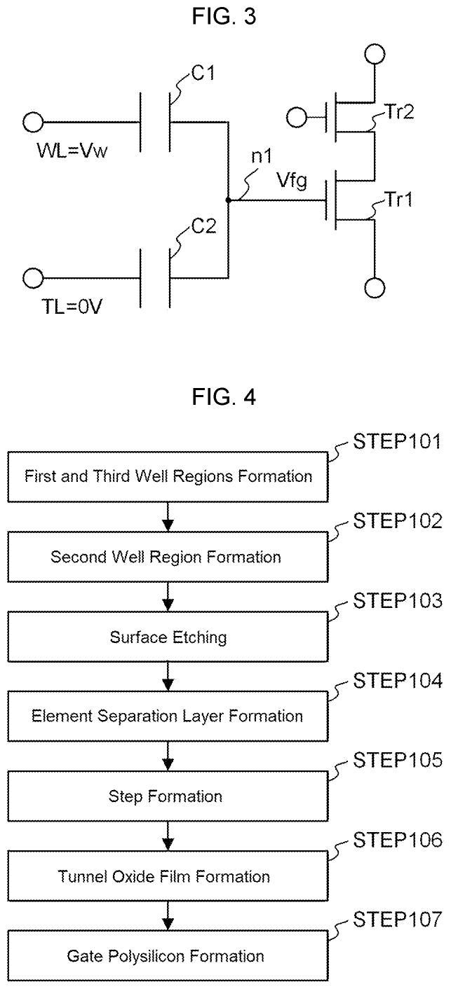

FIG. 3 is a circuit diagram illustrating, as an equivalent circuit, the configuration of the single-layer polysilicon memory cell such as the semiconductor device 100 of this embodiment. In this figure, the capacitor of the control gate constituted of the first well region 11 is C1, the capacitor of the tunnel gate constituted of the third well region 13 is C2, the potential of the floating gate constituted of the gate polysilicon 20 is Vfg, the read-out field effect transistor constituted of the second well region 12 is Tr1, and the selector transistor 23 is Tr2.

When data is to be written, a write-in voltage WL=Vw is applied to one end of the capacitor C1. A write-in voltage TL=0V is applied to one end of the capacitor C2. The potential Vfg of the floating gate is the potential of a node n1 connecting the other end of the capacitor C1 with the other end of the capacitor C2.

It is preferable that the potential Vfg of the floating gate have a value closer to the write-in voltage Vw applied to the control gate. That is, when the potential Vfg of the floating gate is high and at a level close to the write-in voltage Vw, it is possible to create a sufficiently large flow of electrical charges between the tunnel gate and the floating gate (or between the third well region 13 and the gate polysilicon 20) when data is written.

Because the capacitors C1 and C2 have the same amount of electrical charges, the relationship between the capacitance of the capacitors C1 and C2, the potential Vfg of the floating gate, and the write-in voltage Vw can be represented by C1×(Vw−Vfg)=C2×Vfg. Thus, the potential Vfg of the floating gate is obtained from the following formula (Formula 1).

$$Vfg = \frac{1}{1 + \frac{C 2}{C 1}} Vw \qquad Formula 1$$

That is, when the capacitance of the capacitor C1 is higher than that of the capacitor C2, the potential Vfg of the floating gate becomes greater.

Generally, the capacitance of the parallel plate capacitor is represented by the following formula (Formula 2) where C is the capacitance of the capacitor, E is the permittivity, d is the distance between the electrodes, and A is the electrode area.

$$C = \frac{ɛ}{d} A \qquad Formula 2$$

In a single-layer polysilicon type memory cell such as the semiconductor device 100 of this embodiment, when the capacitance of the control gate is C, the electrode area A is the area where the first well region 11 (the control gate) faces the gate polysilicon 20 (the floating gate) across the tunnel oxide film 21. Thus, the larger the area where each well region faces the gate polysilicon 20 across the tunnel oxide film 21, the greater the capacitance becomes, and the smaller this area is, the smaller the capacitance becomes.

As described above, when the capacitance of the first well region 11, i.e., the data write-in capacitor, is larger than the capacitance of the third well region 13, i.e., the erasure capacitor, it will be easier to inject electrical charges to the floating gate, which can enhance the writing performance Therefore, a high writing performance is achieved when the area where the first well region 11 faces the gate polysilicon 20 is larger than the area where the third well region 13 faces the gate polysilicon 20.

In the semiconductor device 100 of this embodiment, the gate polysilicon 20 is formed to cover part of the side faces of the first well region 11 next to the element isolation region 14, in addition to the top surface of the first well region 11. This increases the area where the first well region 11 faces the gate polysilicon 20 across the tunnel oxide film 21. As a result, it is possible to improve the data writing performance.

If the same capacitance of the control gate as that of the semiconductor device 100 of this embodiment is to be achieved with the structure where the gate polysilicon 20 is formed to cover only the top surface of the first well region 11, it would be necessary to further extend the first well 11 and the gate polysilicon 20 in the horizontal direction to increase the overlapping area. This would increase the size of the entire memory cell.

On the other hand, in the semiconductor device 100 of this embodiment, the gate polysilicon 20 is formed to face part of the side faces of the first well region 11. This way, a larger electrode area A is secured, and it is not necessary to increase the overlapping area in the horizontal direction. As a result, the data writing performance is improved without increasing the memory size.

Next, a manufacturing method of the semiconductor device 100 of this embodiment will be explained referring to the manufacturing process flow illustrated in FIG. 4.

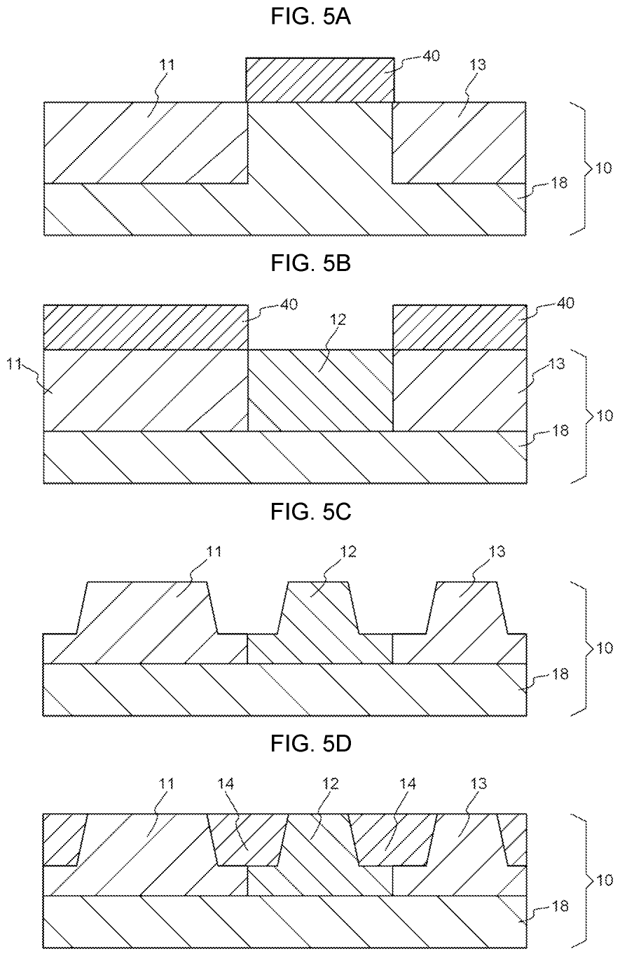

First, as illustrated in FIG. 5A, a resist film 40 is formed on a semiconductor substrate 10 (such as a P-type Si substrate) of the second conductivity type and patterned by photolithography. Then P+ (phosphorus) or As+ (arsenic) is injected to the surface of the semiconductor substrate 10 as impurities of the first conductivity type (N-type in this embodiment), for example. This way, the first well region 11 and the third well region 13 are formed (STEP 101 of FIG. 4).

Next, as illustrated in FIG. 5B, a resist film 40 is formed on the first well region 11 and the third well region 13 on the surface of the semiconductor substrate 10, and impurities of the second conductivity type (P-type in this embodiment) are injected into the substrate surface. This way, the second well region 12 is formed (STEP 102 of FIG. 4).

Next, as illustrated in FIG. 5C, etching is performed to form grooves on the surface of the semiconductor substrate 10 in which the first well region 11, second well region 12, and third well region 13 are formed (STEP 103 of FIG. 4).

Next, as illustrated in FIG. 5D, an insulating film of SiO₂ or the like is formed on the entire surface of the semiconductor substrate 10 including the grooves by the CVD (chemical vapor deposition) method. This way, the element isolation region 14 is formed (STEP 104 of FIG. 4).

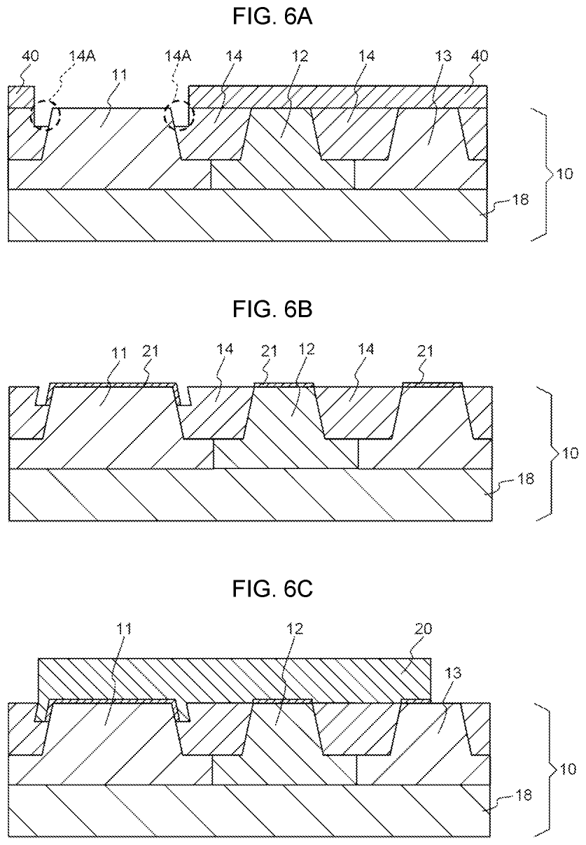

Next, as illustrated in FIG. 6A, a resist film 40, patterned by the photolithography, is formed on the surface of the semiconductor substrate 10, and a part of the element isolation region 14 around the first well region 11 is removed by etching. This way, a step (recess) 14A is formed in the element isolation region 14 around the first well region 11 (STEP 105 of FIG. 4).

Next, as illustrated in FIG. 6B, a silicon oxide film is formed to cover the exposed portions of the first well region 11, second well region 12, and third well region 13 by the thermal oxidation method. This way, the tunnel oxidation film 21 is formed (STEP 106 of FIG. 4).

Next, a polysilicon film is formed to cover the surface of the element isolation region 14 and the surface of the tunnel oxide film 21 by the CVD method. This way, as illustrated in FIG. 6C, the gate polysilicon 20 is formed (STEP 107 of FIG. 4).

After the processes described above, a diffusion layer and contacts are formed by ion injection, and the semiconductor device 100 of this embodiment is completed.

As described above, in the semiconductor device 100 of this embodiment, the gate polysilicon 20 is formed to cover the top surface of the first well region 11 exposed on the first surface of the semiconductor substrate and part of the side faces of the first well region 11 next to the element isolation region 14. This makes it possible to increase the area where the control gate and the floating gate face each other. As a result, the area of the control gate and the floating gate in the direction horizontal to the substrate surface can be reduced as compared with a semiconductor device having the structure in which the gate polysilicon covers only the top surface of the first well region. Thus, according to the semiconductor device 100 of this embodiment, it is possible to provide a non-volatile memory with a small area and sufficient capacity.

### Embodiment 2

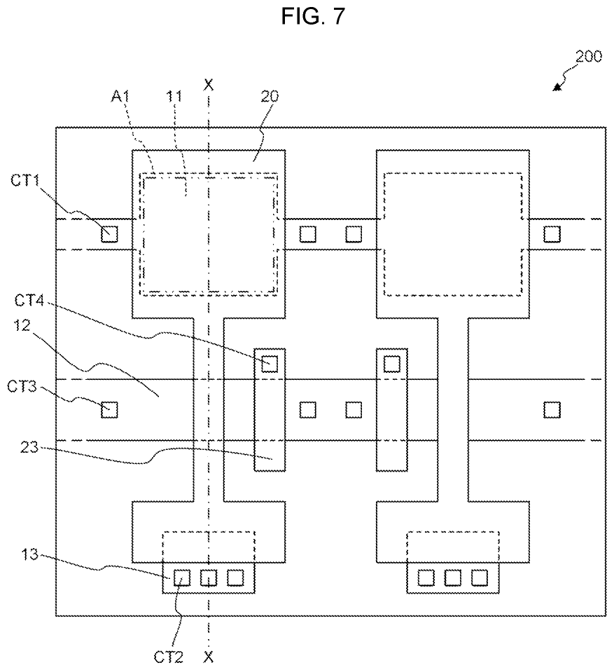

Next, Embodiment 2 of the present invention will be explained. FIG. 7 is a top view of a semiconductor device 200 of Embodiment 2, viewed from above the surface where the elements are formed.

In the semiconductor device 200 of this embodiment, the active region that constitutes the first well region 11 is not formed in the band-like shape having a constant width as described in Embodiment 1. Instead, the first well region 11 has a rectangular region that functions as the control gate and a narrow band-shaped region extending from the rectangular region and connecting to the control gate of an adjacent memory cell in a top view.

In Embodiment 1, only two sides of the rectangular area of the exposed surface of the first well region 11 in the first region A1 on the first surface of the semiconductor substrate 10 were facing the element isolation region 14, but in this embodiment, all four sides of the rectangular area face the element isolation region 14. A step (recess) is formed in a part of the element isolation region 14 facing the first well region 11. That is, in this embodiment, the step of the element isolation region 14 is formed to surround the first well region 11, which is formed to extend from the first region A1.

The gate polysilicon 20 is formed to cover the entire rectangular region. The ridge 20A of the gate polysilicon 20 in this embodiment is formed to surround the first well region 11, filling the step of the element isolation region 14.

In Embodiment 1, recesses are formed in the two sides in the extension direction of the active region out of the four sides constituting the first rectangular portion of the gate polysilicon 20. On the other hand, in this embodiment, the first rectangular portion of the gate polysilicon 20 is formed to cover the entire rectangular area of the first well region, and a ridge is formed in all of the four sides of the first rectangular portion of the gate polysilicon 20.

Therefore, with the configuration of this embodiment, it is possible to further increase the area where the first well region 11 and the gate polysilicon 20 face each other, as compared to the semiconductor device 100 of Embodiment 1. This makes it possible to further improve the data writing performance.

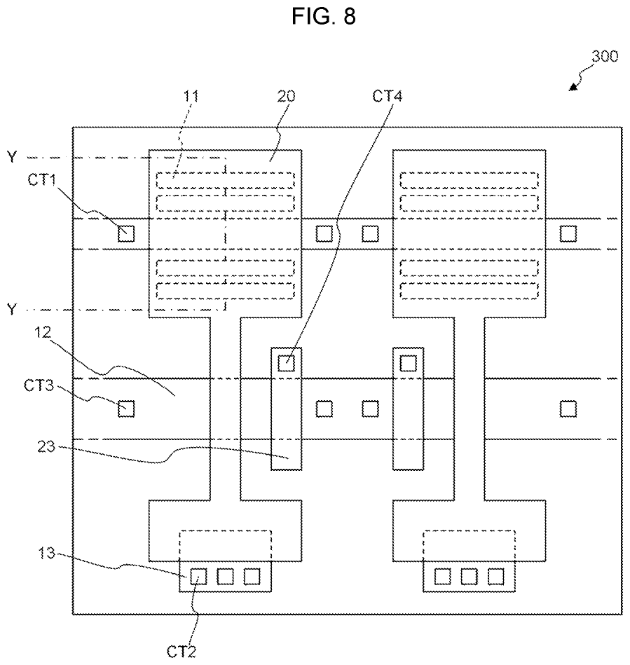

FIG. 8 is a top view of a semiconductor device 300 of a modification example of Embodiment 2, viewed from above the surface where the elements are formed. In the semiconductor device 300 of the modification example, the first well region 11 immediately below the gate polysilicon 20 is constituted of a plurality of strip-shaped regions in a top view.

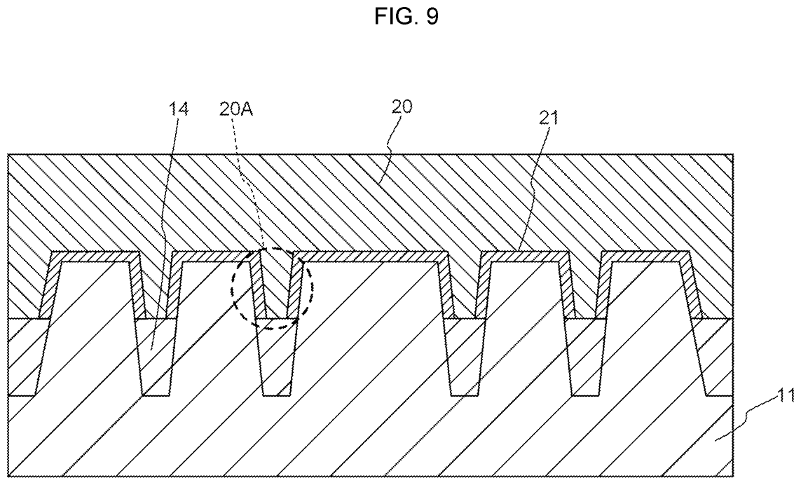

FIG. 9 is a cross-sectional view taken along the Y-Y line of FIG. 8 (that is, a cross-sectional view only showing the area where the first well region 11 is formed). In the semiconductor device 300 of the modification example, grooves are formed between the respective strip-shaped regions. At the bottom of the grooves, the element isolation region 14 is formed, and in the top part of the grooves, ridges of the gate polysilicon 20 are disposed.

With this configuration, the area where the first well region 11 and the gate polysilicon 20 face each other can be made even larger, and the data writing performance can be improved further.

The present invention is not limited to the embodiments described above. For example, in Embodiment 1, an example in which polysilicon (gate polysilicon 20) was used for the conductive layer functioning as the floating gate was explained, but the present invention is not limited to this, and the floating gate may be realized by a conductive layer made of another conductive material, instead of polysilicon.

In the embodiments described above, an example in which the tunnel oxide film 21 is made of a silicon oxide film was explained, but the present invention is not limited to this, and another material having an insulating property may be used.

In the embodiments described above, the element isolation region 14 had a step formed in the part next to the first well region 11, and the gate polysilicon 20 was formed to cover a part of the side face of the first well region 11 in this step. However, the gate polysilicon 20 may be formed in a different manner to cover the side face of the first well region 11. For example, a recess may be formed in the element isolation region 14 to reach the bottom face thereof, and the portion of the element isolation region 14 facing the first well region 11 may be entirely covered by the protrusion 20A of the gate polysilicon 20.

The top-view shapes of the first well region 11, the second well region 12, and the third well region 13 are not limited to those described in the embodiments above.

The manufacturing method described in the embodiments above is merely an example, and a different manufacturing process may also be used. For example, in the embodiments described above, the first well region 11 and the third well region 13 were formed by injecting impurities of the first conductivity type (N-type) into the semiconductor substrate 10 of the second conductivity type (P-type) by ion injection, and then the second well region 12 was formed by injecting impurities of the second conductivity type (P-type) by ion injection. However, the first well region 11 and the third well region 13 may alternatively formed by forming a semiconductor layer of the second conductivity type (P-type) on the surface of the semiconductor substrate 1, for example, and ion-injecting impurities of the first conductivity type (N-type) into the semiconductor layer. In this way, the entire area of the semiconductor layer of the second conductivity type, other than the first well region 11 and the third well region 13, becomes the second well region 12.

What is claimed is:

1. A semiconductor device that constitutes a non-volatile memory, comprising:
a semiconductor substrate;
a first well of a first conductivity type formed to extend inwardly from a first region on a surface of the semiconductor substrate;
a second well of a second conductivity type having an opposite polarity to the first conductivity type, the second well being formed to extend inwardly from a second region separated from the first region on said surface of the semiconductor substrate;
a third well of the first conductivity type formed to extend inwardly from a third region separated from the second region on said surface of the semiconductor substrate; and
a conductive layer formed over the first region, the second region, and the third region on said surface of the semiconductor substrate,
wherein, in said surface, a recess is formed in at least part of a periphery of the first region to expose a side face of the first well, and
wherein the conductive layer is formed to cover a top surface of the first well exposed in the first region and at least part of the side face of the first well exposed in the recess.

2. The semiconductor device according to claim 1, further comprising a separation layer formed to extend inwardly from a region between the first region and the second region on said surface of the semiconductor substrate, the separation layer being in contact with the first well and the second well,
wherein the recess is formed between the first well and the separation layer in a direction along which the first region and the second region are separated.

3. The semiconductor device according to claim 1, wherein an oxide film is formed on a surface of the first well so as to cover the top surface of the first well exposed in the first region and the side face exposed in the recess, and
wherein the conductive layer is formed on the oxide film to extend over the top surface of the first well and at least part of the side face of the first well.

4. The semiconductor device according to claim 3, wherein the conductive layer has a flat plate portion disposed to face the first well in the first region, and a ridge that protrudes from the flat plate portion in a position corresponding to said at least part of the side face of the first well.

5. The semiconductor device according to claim 4, wherein the ridge of the conductive layer is formed to extend inwardly from an area that surrounds the first region on said surface of the semiconductor substrate.

6. The semiconductor device according to claim 1, wherein the first well is a well region that functions as a control gate to receive a first voltage when data is written in the non-volatile memory,
wherein the third well is a well region that functions as a tunnel gate to receive a second voltage that is smaller than the first voltage when data is written in the non-volatile memory, and
wherein the first region has a larger area than the third region.

7. The semiconductor device according to claim 6, wherein the conductive layer is constituted of a polysilicon layer of the first conductivity type, and functions as a floating gate of the non-volatile memory.

8. The semiconductor device according to claim 1, wherein the semiconductor substrate is a semiconductor substrate of the second conductivity type.

9. A semiconductor device, comprising:
a semiconductor substrate having a first well of a first conductivity type formed to extend inwardly from a first region on one surface of the semiconductor substrate, a second well of a second conductivity type having an opposite polarity to the first conductivity type, the second well being formed to extend inwardly from a second region separated from the first region on said surface of the semiconductor substrate, and a third well of the first conductivity type formed to extend inwardly from a third region separated from the second region on said surface of the semiconductor substrate;
a separation layer that extends inwardly from a fourth region between the first region and the second region on said surface of the semiconductor substrate; and
a conductive layer formed over the first region, the second region, the third region, and the fourth region on said surface of the semiconductor substrate, the conductive layer having a part thereof sandwiched between the first well and the separation layer in a direction along which the first region and the second region are separated.

10. A manufacturing method for a semiconductor device that constitutes a non-volatile memory, comprising:
a step of forming a first well of a first conductivity type to extend inwardly from a first region on one surface of a semiconductor substrate, and a third well of the first conductivity type to extend inwardly from a third region separated from the first region on said surface of the semiconductor substrate;
a step of forming a second well of a second conductivity type having an opposite polarity to the first conductivity type, the second well being formed to extend inwardly from a second region located between the first region and the third region on said surface of the semiconductor substrate;
a step of forming a separation layer that extends inwardly from a region located at a border between the first region and the second region on said surface of the semiconductor substrate;
a step of forming a recess in the separation layer to expose part of a side wall of the first well at a border between the separation layer and the first well; and
a step of forming a conductive layer to cover a top surface of the first well exposed in the first region and at least part of the side face of the first well exposed in the recess.
